(19) United States
(12) Patent Application Publication
(10) Pub. No.: US 2009/0101201 A1
(43) Pub. Date: Apr. 23, 2009

(54) NIP-NIP THIN-FILM PHOTOVOLTAIC STRUCTURE

(76) Inventors: John M. White, Hayward, CA (US); Soo Young Choi, Fremont, CA (US)

Correspondence Address: PATTERSON & SHERIDAN, LLP - - APPM/TX, 3040 POST OAK BOULEVARD, SUITE 1500, HOUSTON, TX, 77056, US

(21) Appl. No.: 11/876,359

(22) Filed: Oct. 22, 2007

(51) Int. Cl. H01L 31/045; C23C 16/54; H01L 31/18

(52) U.S. Cl. 136/255; 118/723 R; 438/72; 257/E31.127; 257/E31.045

(57) ABSTRACT

A thin film multi-junction photovoltaic structure is presented as well as methods and apparatus for forming the same. The photovoltaic structure comprises first and second NIP junctions formed over a translucent substrate.

### BACKGROUND OF THE INVENTION

1. Field of the Invention

Embodiments of the present invention generally relate to photovoltaic structures and methods and apparatus for forming the same. More particularly, embodiments of the present invention relate to thin film, multi-junction, photovoltaic structures and methods and apparatus for forming the same.

2. Description of the Related Art

Photovoltaic (PV) structures are devices that convert sunlight into direct current (DC) electrical power. PV structures may be single junction or multi-junction with each junction having a p-doped region, an intrinsic region, and an n-doped region.

In a single junction PV structure, only photons whose energy is equal to or greater than the band gap of the cell material are absorbed and converted to electrical energy. Lower energy photons are not used; therefore, single junction cells are relatively inefficient. Multi-junction cells are more efficient since more PIN junctions exist to absorb the photons.

The typical thin-film, multi-junction, PV structure is a PIN-PIN. During the PIN-PIN manufacturing process, the active, absorbing, silicon layers are typically deposited onto a glass substrate. Thus, PIN-PIN PV structure manufacturing allows for simple, creation and interconnection of the individual cells in a single PV module panel via laser scribing techniques.

However, tempered glass front surfaces (surfaces that face the sun) are typically preferred in certain industries for protection of PV panels. This adds complexity and expense to PIN-PIN PV structure manufacturing because the PIN-PIN process requires that the substrate material be the surface that is exposed to the sun, and it is extremely difficult to manufacture tempered glass to the required level of flatness needed for the thin film deposition process. Further, tempered glass cannot be cut subsequent to the tempering process, which precludes manufacturing large PV panels and later cutting them to smaller sizes needed for particular applications. Therefore, if tempered glass protection of a PIN-PIN PV panel is desired, a sheet of tempered glass must be added to the surface of the substrate subsequent to the deposition process.

Additionally, the PIN-PIN process requires the use of high purity (low iron) glass substrates because the substrate must allow high transmission of all wavelengths (particularly shorter wavelengths) of the solar spectrum to maximize the efficiency of the multi-junction PV structure.

Therefore, a need exists for improved thin film, multi-junction, PV structures and methods and apparatus for forming the same in a factory environment.

### SUMMARY OF THE INVENTION

The present invention generally comprises thin film, multi-junction PV structures and methods and apparatus for forming the same. In particular, the present invention comprises improved NIP-NIP structures and methods and apparatus for forming the same.

In one embodiment, a method of forming a thin film multi-junction photovoltaic structure comprises selecting a translucent or transparent substrate, forming a first transparent conductive oxide layer over the substrate, forming a first NIP junction over the first transparent conductive oxide layer, forming a second NIP junction over the first NIP junction, forming a second transparent conductive oxide layer over the second NIP junction, applying a top encapsulation layer over the second transparent conductive oxide layer, and forming a reflective layer under the substrate. Forming the first NIP junction may comprise forming an n-type silicon layer, forming an intrinsic type microcrystalline silicon layer over the n-type silicon layer, and forming a p-type silicon layer over the intrinsic type microcrystalline silicon layer. Forming the second NIP junction may comprise forming an n-type silicon layer, forming an intrinsic type amorphous silicon layer over the n-type silicon layer, and forming a p-type silicon layer over the intrinsic type amorphous silicon layer.

In one embodiment, a thin film, multi-junction, photovoltaic structure, comprises a translucent or transparent substrate, a first transparent conductive oxide layer formed over the substrate, a first NIP junction formed over the first transparent conductive oxide layer, a second NIP junction formed over the first NIP junction, a second transparent conductive oxide layer formed over the second NIP junction, an encapsulation layer applied over the second transparent conductive oxide layer, and a reflective layer formed under the substrate. The first NIP junction may comprise an n-type silicon layer, an intrinsic type microcrystalline silicon layer formed over the n-type silicon layer, and a p-type silicon layer formed over the intrinsic type microcrystalline silicon layer. The second NIP junction may comprise an n-type silicon layer, an intrinsic type amorphous silicon layer formed over the n-type silicon layer, and a p-type silicon layer formed over the intrinsic type amorphous silicon layer.

In one embodiment, a method of forming a thin film multi-junction photovoltaic structure comprises selecting a translucent or transparent substrate, forming a first transparent conductive oxide layer over the substrate, performing a first laser scribing process through the substrate, wherein a strip of the first transparent conductive oxide layer is ablated, forming a first NIP junction over the first transparent conductive oxide layer, forming a second NIP junction over the first NIP junction, performing a second laser scribing process through the substrate, wherein a first strip of the first and second NIP junctions are ablated, forming a second transparent conductive oxide layer over the second NIP junction, performing a third laser scribing process through the substrate, wherein a second strip of the first and second NIP junctions are ablated and a strip of the second transparent conductive oxide layer covering the second strip of the first and second NIP junctions is removed, applying a top encapsulation layer over the second transparent conductive oxide layer, and forming a reflective layer under the substrate. Forming the first NIP junction may comprise forming an n-type silicon layer, forming an intrinsic type microcrystalline silicon layer over the n-type silicon layer, and forming a p-type silicon layer over the intrinsic type microcrystalline silicon layer. Forming the second NIP junction may comprise forming an n-type silicon layer, forming an intrinsic type amorphous silicon layer over the n-type silicon layer, and forming a p-type silicon layer over the intrinsic type amorphous silicon layer.

In one embodiment, an apparatus for forming a thin film multi-junction photovoltaic structure comprises a first system configured to form a first NIP junction, and a second system configured to form a second NIP junction over the first NIP junction. The first system may comprise an n-chamber configured to deposit an n-type silicon layer and a p-chamber configured to deposit a p-type silicon layer. The second system may comprise an n-chamber configured to deposit an n-type silicon layer and a p-chamber configured to deposit a p-type silicon layer.

In one embodiment, an apparatus for forming a thin film multi-junction photovoltaic structure comprises a first system configured to form a first NIP junction and a second system configured to form a second NIP junction over the first NIP junction. The first system may comprise a chamber configured to deposit an n-type silicon layer, an intrinsic type microcrystalline silicon layer, and a p-type silicon layer. The second system may comprise a chamber configured to deposit an n-type silicon layer, an intrinsic type amorphous silicon layer, and a p-type silicon layer.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a schematic diagram of certain embodiments of a multi-junction, PV structure oriented toward the light or solar radiation.

FIG. 2 is a is a schematic diagram of the multi-junction, PV structure of FIG. 1 further comprising an n-type amorphous silicon buffer layer.

FIG. 3 is a schematic diagram of the multi-junction, PV structure of FIG. 1 further comprising a p-type microcrystalline silicon contact layer.

FIG. 4 is a schematic cross-section view of one embodiment of a plasma enhanced chemical vapor deposition (PECVD) chamber in which one or more films of a PV structure may be deposited.

FIG. 5 is a top schematic view of one embodiment of a process system having a plurality of process chamber.

### DETAILED DESCRIPTION

The present invention generally comprises thin film, multi-junction PV structures and methods and apparatus for forming the same. In particular, the present invention comprises improved NIP-NIP structures and methods and apparatus for forming the same.

The NIP-NIP structure involves a more difficult manufacturing process than the PIN-PIN structure, but the NIP-NIP structure has the potential to achieve higher conversion efficiency at higher deposition rates, resulting in lower cost per watt than the PIN-PIN structure.

In current NIP-NIP, PV manufacturing, a metal or metal-coated substrate is used to create the back electrical contact and provide the back reflecting surface needed to increase the light capturing efficiency of the PV module. The active, absorbing, silicon layers are deposited onto this metal surface, which leads to difficulty in separating the panel into interconnected, multiple cells without damaging the performance of the cells.

Certain embodiments of the present invention are NIP-NIP, PV structures that allow a simpler PIN-PIN laser scribing manufacturing process to be used for separating the structure into interconnected, multiple cells without damaging the performance of the cells. This is accomplished by separating the functions of the back electrical contact and the back reflector.

In embodiments of the present invention, the back contact function is provided by a transparent conducting oxide (TCO) layer, which performs the function of the front contact TCO layer in a PIN-PIN device structure. The back reflector function is provided by a separate reflective coating, which is applied to the substrate after the laser scribing process is performed.

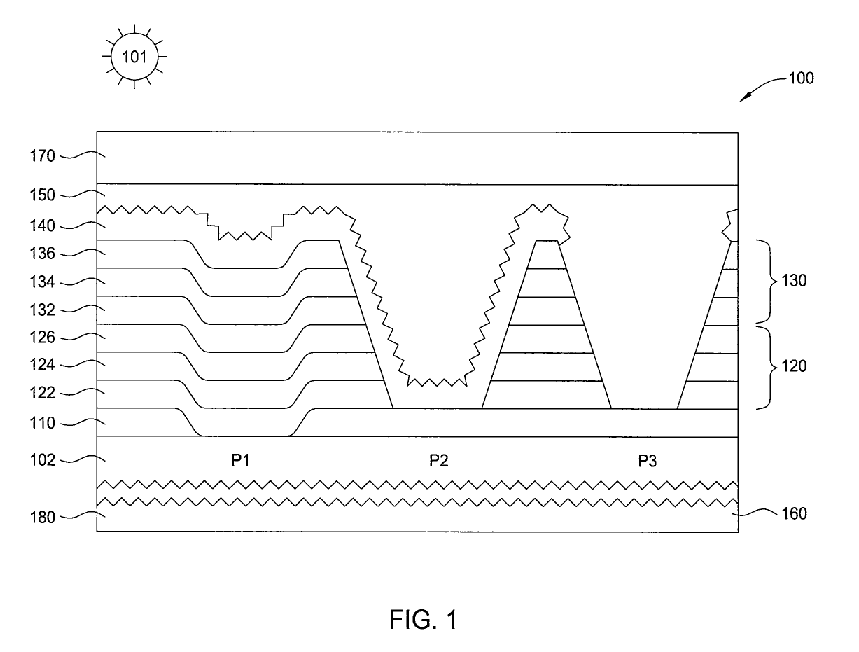

FIG. 1 is a schematic diagram of an embodiment of a multi-junction PV structure 100 oriented toward the light or solar radiation 101. PV structure 100 comprises a translucent or transparent substrate 102, such as a glass substrate, polymer substrate, or other suitable substrate with thin films formed thereover. In the present embodiment, substrate 102 may be a lower purity, less expensive substrate than that required by corresponding PIN-PIN structures, such as a standard, inexpensive glass substrate. This is because with the NIP-NIP structure, it is not necessary for the shorter wavelengths of the solar spectrum to be transmitted through substrate 102 because light does not enter the device through the substrate 102. In contrast, light must enter a PIN-PIN structure through the glass substrate; thus, the substrate must be a high purity, low iron glass to allow transmission of the shorter wavelengths of the solar spectrum.

The PV structure 100 further comprises a first transparent conducting oxide (TCO) layer 110 formed over the substrate 102, a first NIP junction 120 formed over the first TCO layer 110, a second NIP junction 130 formed over the first NIP junction 120, a second TCO layer 140 formed over the second NIP junction 130, a top encapsulation layer 150 formed over the second TCO layer 140, and a reflective layer 160 formed under the substrate 102 on the side opposite the first TCO layer 110.

The top encapsulation layer 150 may comprise an optical polymeric resin such as polyvinyl butyral (PVB). Additionally, protective layer 170 may be affixed to the top encapsulation layer 150, before or after cutting the PV structure 100 to the appropriate size(s). Protective layer 170 may be a high quality, low iron glass, which may be tempered glass, if desired.

The reflective layer 160 may comprise Al, Ag, Ti, Cr, Au, Cu, Pt, alloys thereof or combinations thereof. Alternatively, the reflective layer 160 may comprise other reflective materials such as white or silver reflective coatings. Additionally, a protective coating 180 may be formed under the reflective layer 160.

The first TCO layer 110 and the second TCO layer 140 may each comprise tin oxide, zinc oxide, indium tin oxide, cadmium stannate, combinations thereof, or other suitable materials. The TCO materials may also include additional dopants and components. For example, zinc oxide may further include dopants, such as aluminum, gallium, boron, and other suitable dopants. Zinc oxide preferably comprises 5% atomic or less of dopants, and more preferably comprises 2.5% atomic or less aluminum. Additionally, in certain instances, the substrate 102 may be provided by a glass manufacturer with the first TCO layer 110 already provided.

The first NIP junction 120 may comprise an n-type microcrystalline or amorphous silicon layer 122 formed over the first TCO layer 110, an intrinsic type microcrystalline silicon layer 124 formed over the n-type microcrystalline or amorphous silicon layer 122, and a p-type microcrystalline or amorphous silicon layer 126 formed over the intrinsic type microcrystalline silicon layer 124. In certain embodiments, the n-type microcrystalline or amorphous silicon layer 122 may be formed to a thickness between about 100 Å and about 400 Å. In certain embodiments, the intrinsic type microcrystalline silicon layer 124 may be formed to a thickness between about 10,000 Å and about 30,000 Å. In certain embodiments, the p-type microcrystalline or amorphous silicon layer 126 may be formed to a thickness between about 100 Å and about 400 Å.

The second NIP junction 130 may comprise an n-type microcrystalline or amorphous silicon layer 132 formed over the p-type microcrystalline or amorphous silicon layer 126, an intrinsic type amorphous silicon layer 134 formed over the n-type microcrystalline or amorphous silicon layer 132, and a p-type amorphous silicon layer 136 formed over the intrinsic type amorphous silicon layer 134. In certain embodiments, the n-type microcrystalline or amorphous silicon layer 132 may be formed to a thickness between about 100 Å and about 400 Å. In certain embodiments, the intrinsic type amorphous silicon layer 134 may be formed between about 1,500 Å and about 3,500 Å. In certain embodiments the p-type amorphous silicon layer may be formed between about 60 Å and about 300 Å.

Solar radiation 101 is absorbed by the intrinsic layers of the NIP junctions 130, 120 and is converted to electron-hole pairs. The electric field created between the p-type layer and the n-type layer that stretches across the intrinsic layer causes electrons to flow toward the n-type layers and holes to flow toward the p-type layers, creating current. The second NIP junction 130 comprises an intrinsic type amorphous silicon layer 134, and the first NIP junction 120 comprises an intrinsic type microcrystalline silicon layer 124. These layers are stacked such that solar radiation 101 first strikes the intrinsic type amorphous silicon layer 134 and then strikes the intrinsic type microcrystalline silicon layer 124 because amorphous silicon has a larger band gap than microcrystalline silicon. Solar radiation not absorbed by the second NIP junction 130 continues on to the first NIP junction 120. Therefore, the multi-junction, PV structure 100 is more efficient than its single junction counterparts since it captures a larger portion of the solar radiation spectrum.

To improve light absorption, the substrate 102 may be textured by wet, plasma, ion, and/or mechanical processes on the side adjacent the reflective layer 160, prior to depositing the reflective layer 160 onto the substrate 102. To further improve light absorption, the second TCO layer 140 may be textured on the side opposite the second NIP junction 130 as well.

In one aspect, the multi-junction, PV cell 100 does not need an additional conductive tunnel layer between the second NIP junction 130 and the first NIP junction 120 because the n-type microcrystalline silicon layer 132 of the second NIP junction 130 and the p-type microcrystalline silicon layer 126 of the first NIP junction 120 have sufficient conductivity to provide a tunnel junction to allow electrons to flow from the second NIP junction 130 to the first NIP junction 120.

Additionally, the amorphous silicon layers of the second NIP junction 130 may provide increased cell efficiency since they are more resistant to attack from oxygen, such as the oxygen in air. Oxygen may attack the silicon films and form impurities, which lower the capability of the films to participate in electron/hole transport therethrough. However, since the microcrystalline layers are formed beneath the amorphous silicon layers during manufacturing, improved grain boundary control, and thereby, oxygen contamination control may be improved.

Moreover, high radio frequency (RF) power is desirable during deposition of microcrystalline films because high quality microcrystalline films may be produced at high deposition rates translating to lower costs. However, high power can cause the substrate temperature to rise too high and degrade the energy conversion efficiency of the PV structure if overheating occurs at the wrong time in the multilayer silicon deposition sequence. Embodiments of the present invention allow high power to be applied to the deposition process for growth of the thick microcrystalline silicon layers without overheating of the critical boron-doped (p-type) layers that are deposited after the intrinsic microcrystalline silicon layer 124.

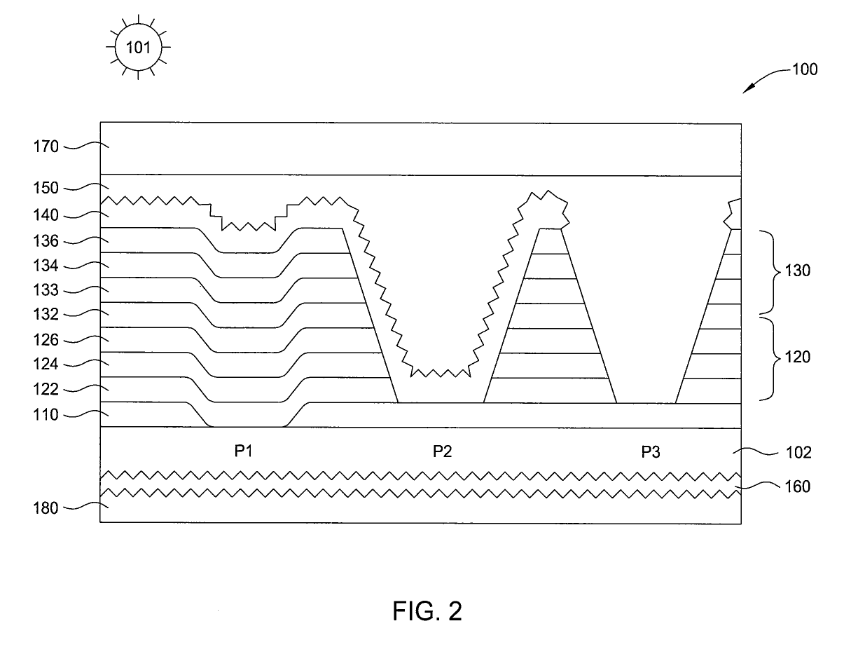

FIG. 2 is a schematic diagram of the multi-junction, PV cell 100 of FIG. 1 further comprising an n-type amorphous silicon buffer layer 133 formed between the n-type microcrystalline silicon layer 132 and the intrinsic type amorphous silicon layer 134. In certain embodiments, the n-type amorphous silicon buffer layer 133 may be formed to a thickness between about 10 Å and about 200 Å. The n-type amorphous silicon buffer layer 133 may help bridge the band gap offset that may exist between the intrinsic type amorphous silicon layer 134 and the n-type microcrystalline silicon layer 132. Thus, cell efficiency may be improved due to enhanced current collection.

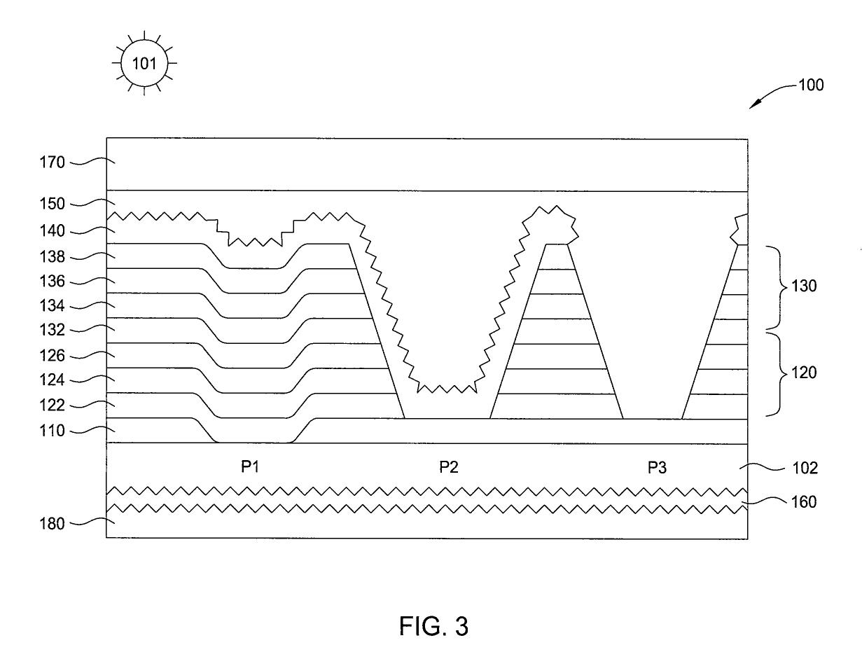

FIG. 3 is a schematic diagram of the multi-junction, PV cell 100 of FIG. 1 further comprising a p-type microcrystalline silicon contact layer 138 formed between the second TCO layer 140 and the p-type amorphous silicon layer 136. In certain embodiments, the p-type microcrystalline silicon contact layer 138 may be formed to a thickness between about 60 Å and about 300 Å. The p-type microcrystalline silicon contact layer 138 may help achieve low resistance contact with the TCO layer. Thus, the cell efficiency may be improved since current flow between the intrinsic type amorphous silicon layer 134 and the second TCO layer 140 may be improved. Additionally, the multi-junction, PV cell 100 of FIG. 3 may further comprise an n-type amorphous silicon buffer layer 133 formed between the intrinsic type amorphous silicon layer 134 and the n-type microcrystalline semiconductor layer 132 as described in FIG. 2.

In embodiments of the present invention, individual, multi-junction NIP cells may be created and interconnected in a single PV module using laser scribing techniques similar to those used to create and interconnect multi-junction, PIN cells. Additionally, unlike prior art NIP structures that are deposited onto metal substrates, in embodiments of the present invention, laser scribing may be performed through the substrate 102 prior to depositing the reflective layer 160 because embodiments of the present invention separate the functions of the back electrical contact (110) and the back reflector (160).

As can be seen in FIGS. 1-3, the first TCO layer 110 is first deposited onto substrate 102. Next, during the formation of a first trench P1, the TCO layer 110 may be ablated through the substrate 102 with a long wavelength laser, for example about 1064 nm. The first NIP junction 120 may next be deposited, followed by the second NIP junction 130. Next, a second trench P2 may be formed through the substrate P2 with a shorter wavelength laser, for example about 532 nm. The second TCO layer 140 may then be deposited. Subsequently, a third trench P3 may be formed using a shorter wavelength laser, for example about 532 nm.

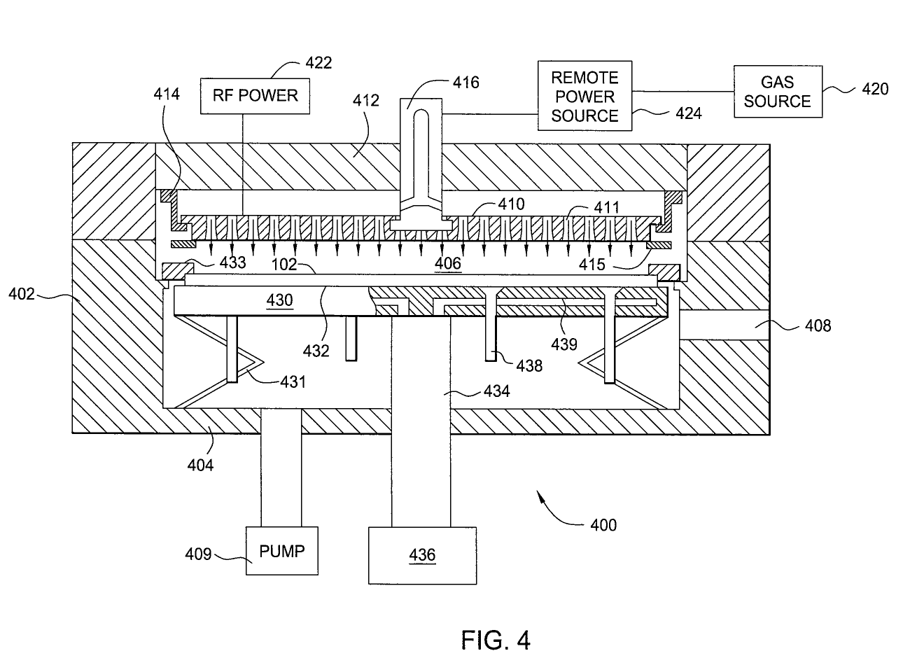

FIG. 4 is a schematic cross-section view of one embodiment of a plasma enhanced chemical vapor deposition (PECVD) chamber 400 in which one or more films of a PV cell, such as the PV structure 100 shown in FIGS. 1-3, may be deposited. One suitable plasma enhanced chemical vapor deposition chamber is available from Applied Materials, Inc., located in Santa Clara, Calif. It is contemplated that other deposition chambers, including those from other manufacturers, may be utilized to practice the present invention.

The chamber 400 generally includes walls 402, a bottom 404, a showerhead 410, and a substrate support 430, which cumulatively define a process volume 406. The process volume is accessed through a valve 408 such that the substrate, such as substrate 102, may be transferred in and out of the chamber 400. The substrate support 430 includes a substrate receiving surface 432 for supporting a substrate and stem 434 coupled to a lift system 436 to raise and lower the substrate support 430. A shadow form 433 may be optionally placed over the periphery of the substrate 102. Lift pins 438 are moveably disposed through the substrate support 430 to move a substrate to and from the substrate receiving surface 432. The substrate support 430 may also include heating and/or cooling elements 439 to maintain the substrate support 430 at a desired temperature. The substrate support 430 may also include grounding straps 431 to provide RF grounding at the periphery of the substrate support 430. Examples of grounding straps are disclosed in U.S. Pat. No. 6,024,044 issued on Feb. 15, 2000 to Law et al. and U.S. patent application Ser. No. 11/613,934 filed on Dec. 20, 2006 to Park et al., which are both incorporated by reference in their entirety to the extent not inconsistent with the present disclosure.

The showerhead 410 is coupled to a backing plate 412 at its periphery by a suspension 414. The showerhead 410 may also be coupled to the backing plate by one or more center supports 416 to help prevent sag and/or control the straightness/curvature of the showerhead 410. A gas source 420 is coupled to the backing plate 412 to provide gas through the backing plate 412 and through the showerhead 410 to the substrate receiving surface 432. A vacuum pump 409 is coupled to the chamber 400 to control the process volume 406 at a desired pressure. An RF power source 422 is coupled to the backing plate 412 and/or to the showerhead 410 to provide an RF power to the showerhead 410 so that an electric field is created between the showerhead and the substrate support so that a plasma may be generated from the gases between the showerhead 410 and the substrate support 430. Various RF frequencies may be used, such as a frequency between about 0.3 MHz and about 200 MHz. In one embodiment the RF power source is provided at a frequency of 13.56 MHz. Examples of showerheads are disclosed in U.S. Pat. No. 6,477,980 issued on Nov. 12, 2002 to White et al., U.S. Publication 2005/0251990 published on Nov. 17, 2006 to Choi et al., and U.S. Publication 2006/0060138 published on Mar. 23, 2006 to Keller et al., which are all incorporated by reference in their entirety to the extent not inconsistent with the present disclosure.

A remote plasma source 424, such as an inductively coupled remote plasma source, may also be coupled between the gas source and the backing plate. Between processing substrates, a cleaning gas may be provided to the remote plasma source 424 so that remote plasma is generated and provided to clean chamber components. The cleaning gas may be further excited by the RF power source 422 provided to the showerhead. Suitable cleaning gases include, but are not limited to NF₃, F₂, and SF₆. Examples of remote plasma sources are disclosed in U.S. Pat. No. 5,788,778 issued Aug. 4, 1998 to Shang et al., which is incorporated by reference to the extent not inconsistent with the present disclosure.

The deposition methods for one or more silicon layers, such as one or more of the silicon layers of PV structure in FIGS. 1-3, may include the following deposition parameters in the process chamber of FIG. 4 or other suitable chamber. A substrate having a surface area of 10,000 cm² or more, preferably 40,000 cm² or more, and more preferably 55,000 cm² or more is provided to the chamber. After processing, the substrate may be cut to form smaller PV cells.

In one embodiment, the heating and/or cooling elements 439 may be set to provide a substrate support temperature during deposition of about 400° C. or less, preferably between about 100° C. and about 300° C., such as about 200° C.

The spacing during deposition between the top surface of a substrate disposed on the substrate receiving surface 432 and the showerhead 410 may be between about 400 mils and about 1,200 mils, preferably between about 400 mils and about 800 mils.

For deposition of silicon films, a silicon-based gas and a hydrogen-based gas are provided. Suitable silicon-based gases include, but are not limited to, silane (SiH₄), disilane (Si₂H₆), silicon tetrafluoride (SiF₄), silicon tetrachloride (SiCl₄), dichlorosilane (SiH₂Cl₂), and combinations thereof. Suitable hydrogen-based gases include, but are not limited to hydrogen gas (H₂). The p-type dopants of the p-type silicon layers may each comprise a group III element, such as boron or aluminum. Preferably, boron is used as the p-type dopant. Examples of boron-containing sources include trimethylboron (TMB or B(CH₃)₃), diborane (B₂H₆), BF₃, B(C₂H₅)₃, and similar compounds. Preferably, TMB is used as the p-type dopant. The n-type dopants of the n-type silicon layer may each comprise a group V element, such as phosphorus, arsenic, or antimony. Preferably, phosphorus is used as the n-type dopant. Examples of phosphorus-containing sources include phosphine and similar compounds. The dopants are typically provided with a carrier gas, such as argon, helium, and other suitable compounds, or with a portion of the hydrogen-based gases. In the process regimes disclosed herein, a total flow rate of hydrogen gas is provided. Therefore, if a hydrogen gas is provided with the dopant, the remainder of the hydrogen gas is separately provided to the chamber.

Certain embodiments of depositing an n-type microcrystalline silicon layer, such as the silicon layer 122 of FIGS. 1-3 may comprise providing a gas mixture of hydrogen gas to silane gas in a ratio of about 100:1 or more. Silane gas may be provided at a flow rate between about 0.1 sccm/L and about 0.8 sccm/L. Hydrogen gas may be provided at a flow rate between about 30 sccm/L and about 250 sccm/L. Phosphine may be provided at a flow rate between about 0.0005 sccm/L and about 0.004 sccm/L. In other words, if phosphine is provided in a 0.5% molar or volume concentration in a carrier gas, then the dopant/carrier gas mixture may be provided at a flow rate between about 0.1 sccm/L and about 0.8 sccm/L. The flow rates in the present disclosure are expressed as sccm per interior chamber volume. The interior chamber volume is defined as the volume of the interior of the chamber in which a gas can occupy. For example, the interior chamber volume of chamber 400 is the volume defined by the backing plate 412 and by the walls 402 and bottom 404 of the chamber minus the volume occupied therein by the showerhead assembly (i.e., including the showerhead 410, suspension 414, center support 415) and by the substrate support assembly (i.e., substrate support 430, grounding straps 431). An RF power between about 100 mW/cm² and about 900 mW/cm² may be provided to the showerhead. The pressure of the chamber may be maintained between about 1 Torr and about 100 Torr, preferably between about 3 Torr and about 20 Torr, more preferably between about 4 Torr and about 12 Torr. The deposition rate of the n-type microcrystalline silicon layer may be about 50 Å/min or more. The n-type microcrystalline silicon layer has a crystalline fraction between about 20% and about 80%, preferably between about 50% and about 70%.

Certain embodiments of depositing an n-type amorphous silicon layer, such as the silicon layer 122 of FIGS. 1-3, may comprise providing hydrogen gas to silicon gas in a ratio of about 20:1 or less. Silane gas may be provided at a flow rate between about 1 sccm/L and about 10 sccm/L. Hydrogen gas may be provided at a flow rate between about 4 sccm/L and about 50 sccm/L. Phosphine may be provided at a flow rate between about 0.0005 sccm/L and about 0.0075 sccm/L. In other words if phosphine is provided in a 0.5% molar or volume concentration in a carrier gas, then the dopant/carrier gas mixture may be provided at a flow rate between about 0.1 sccm/L and about 1.5 sccm/L. An RF power between about 15 mW/cm² and about 250 mW/cm² may be provided to the showerhead. The pressure of the chamber may be maintained between about 0.1 Torr and 20 Torr, preferably between about 0.5 Torr and about 4 Torr. The deposition rate of the n-type amorphous silicon layer may be about 200 Å/min or more.

Certain embodiments of depositing an intrinsic type microcrystalline silicon layer, such as silicon layer 124 of FIGS. 1-3, may comprise providing a gas mixture of silane gas to hydrogen gas in a ratio between 1:20 and 1:200. Silane gas may be provided at a flow rate between about 0.5 sccm/L and about 5 sccm/L. Hydrogen gas may be provided at a flow rate between about 40 sccm/L and about 400 sccm/L. In certain embodiments, the silane flow rate may be ramped up from a first flow rate to a second flow rate during deposition. In certain embodiments, the hydrogen flow rate may be ramped down from a first flow rate to a second flow rate during deposition. An RF power between about 300 mW/cm² or greater, preferably 600 mW/cm² or greater, may be provided to the showerhead. In certain embodiments, the power density may be ramped down from a first power density to a second power density during deposition. The pressure of the chamber is maintained between about 1 Torr and about 100 Torr, preferably between about 3 Torr and about 20 Torr, more preferably between about 4 Torr and about 12 Torr. The deposition rate of the intrinsic type microcrystalline silicon layer may be about 200 Å/min or more, preferably about 500 Å/min. Methods and apparatus for deposited microcrystalline intrinsic layer are disclosed in U.S. patent application Ser. No. 11/426,127 filed Jun. 23, 2006, entitled “Methods and Apparatus for Depositing a Microcrystalline Silicon Film for Photovoltaic Device,” which is incorporated by reference in its entirety to the extent not inconsistent with the present disclosure. The microcrystalline silicon intrinsic layer has a crystalline fraction between about 20% and about 80%, preferably between about 55% and about 75%.

Certain embodiments of depositing a p-type microcrystalline silicon layer, such as silicon layer 126 of FIGS. 1-3 may comprise providing a gas mixture of hydrogen gas to silane gas in a ratio of about 200:1 or greater. Silane gas may be provided at a flow rate between about 0.1 sccm/L and about 0.8 sccm/L. Hydrogen gas may be provided at a flow rate between about 60 sccm/L and about 500 sccm/L. Trimethylboron may be provided at a flow rate between about 0.0002 sccm/L and about 0.0016 sccm/L. In other words, if trimethylboron is provided in a 0.5% molar or volume concentration in a carrier gas, then the dopant/carrier gas mixture may be provided at a flow rate between about 0.04 sccm/L and about 0.32 sccm/L. An RF power between about 50 mW/cm² and about 700 mW/cm² may be provided to the shower head. The pressure of the chamber may be maintained between about 1 Torr and about 100 Torr, preferably between about 3 Torr and about 20 Torr, more preferably between about 4 Torr and about 12 Torr. The deposition rate of the p-type microcrystalline silicon layer may be about 10 Å/min or more. The p-type microcrystalline silicon layer has a crystalline fraction between about 20% and about 80%, preferably between about 50% and about 70%.

Certain embodiments of depositing an n-type microcrystalline silicon layer, such as the silicon layer 132 of FIGS. 1-3 may comprise providing a gas mixture of hydrogen gas to silane gas in a ratio of about 100:1 or more. Silane gas may be provided at a flow rate between about 0.1 sccm/L and about 0.8 sccm/L and about 250 sccm/L. Phosphine may be provided at a flow rate between about 0.0005 sccm/L and about 0.004 sccm/L. In other words, if phosphine is provided in a 0.5% molar or volume concentration in a carrier gas, then the dopant/carrier gas may be provided at a flow rate between about 0.1 sccm/L and about 0.8 sccm/L. An RF power between about 100 mW/cm² and about 900 mW/cm² may be provided to the showerhead. The pressure of the chamber may be maintained between about 1 Torr and about 100 Torr, preferably between about 3 Torr and about 20 Torr, more preferably between about 4 Torr and about 12 Torr. The deposition rate of the n-type microcrystalline silicon layer may be about 50 Å/min or more. The n-type microcrystalline silicon layer has a crystalline fraction between about 20% and about 80%, preferably between about 50% and about 70%.

Certain embodiments of depositing an n-type amorphous silicon buffer layer, such as the silicon layer 133 of FIG. 2, may comprise providing hydrogen gas to silicon gas in a ratio of about 20:1 or less. Silane gas may be provided at a flow rate between about 1 sccm/L and about 10 sccm/L. Hydrogen gas may be provided at a flow rate between about 4 sccm/L and about 50 sccm/L. Phosphine may be provided at a flow rate between about 0.0005 sccm/L and about 0.0075 sccm/L. In other words if phosphine is provided in a 0.5% molar or volume concentration in a carrier gas, then the dopant/carrier gas mixture may be provided at a flow rate between about 0.1 sccm/L and about 1.5 sccm/L. An RF power between about 15 mW/cm² and about 250 mW/cm² may be provided to the showerhead. The pressure of the chamber may be maintained between about 0.1 Torr and 20 Torr, preferably between about 0.5 Torr and about 4 Torr. The deposition rate of the n-type amorphous silicon buffer layer may be about 200 Å/min or more.

Certain embodiments of depositing an intrinsic type amorphous silicon layer, such as the silicon layer 134 of FIGS. 1-3, comprises providing a gas mixture of hydrogen gas to silane gas in a ratio of about 20:1 or less. Silane gas may be provided at a flow rate between about 0.5 sccm/L and about 7 sccm/L. Hydrogen gas may be provided at a flow rate between about 5 sccm/L and 60 sccm/L. An RF power between about 15 MW/cm² and about 250 mW/cm² may be provided to the showerhead. The pressure of the chamber may be maintained between about 0.1 Torr and 20 Torr, preferably between about 0.5 Torr and about 5 Torr. The deposition rate of the intrinsic type amorphous silicon layer may be about 100 Å/min or more.

Certain embodiments of depositing a p-type amorphous silicon layer, such as the silicon layer 136 of FIGS. 1-3, may comprise providing a gas mixture of hydrogen gas to silane gas in a ratio of about 20:1 or less. Silane gas may be provided at a flow rate between about 1 sccm/L and about 10 sccm/L. Hydrogen gas may be provided at a flow rate between about 5 sccm/L and 60 sccm/L. Trimethylboron may be provided at a flow rate between about 0.005 sccm/L and about 0.05 sccm/L. In other words, if trimethylboron is provided in a 0.5% molar or volume concentration in a carrier gas, then the dopant/carrier gas mixture may be provided at a flow rate between about 1 sccm/L and about 10 sccm/L. Methane may be provided at a flow rate between about 1 sccm/L and about 15 sccm/L. An RF power between about 15 mW/cm² and about 200 mW/cm² may be provided to the showerhead. The pressure of the chamber is maintained between about 0.1 Torr and about 20 Torr, preferably between about 1 Torr and about 4 Torr. The deposition rate of the p-type amorphous silicon layer may be about 100 Å/min or more. Methane or other carbon containing compounds, such as C₃H₈, C₄H₁₀, or C₂H₂, may be used to improve the window properties (e.g. to lower absorption of solar radiation) of p-type amorphous silicon layer. Thus, an increased amount of solar radiation may be absorbed through the intrinsic layers and thus cell efficiency is improved.

Certain embodiments of depositing a p-type microcrystalline silicon contact layer, such as contact layer 138 of FIG. 3, may comprise providing a gas mixture of hydrogen gas to silane gas in ratio of about 200:1 or greater. Silane gas may be provided at a flow rate between about 0.1 sccm/L and about 0.8 sccm/L. Hydrogen gas may be provided at a flow rate between about 60 sccm/L and about 500 sccm/L. Trimethylboron may be provided at a flow rate between about 0.0002 sccm/L and about 0.0016 sccm/L. In other words, if trimethylboron is provided in a 0.5% molar or volume concentration in a carrier gas, then the dopant/carrier gas mixture may be provided at a flow rate between about 0.04 sccm/L and about 0.32 sccm/L. An RF power between about 50 mW/cm² and about 700 mW/cm² may be provided to the showerhead. The RF powers in the present disclosure are expressed as Watts supplied to an electrode per substrate area. For example, for an RF power of 10,385 W supplied to a showerhead to process a substrate having dimensions of 220 cm×260 cm, the RF power would be 10,385 W/(220 cm×260 cm)=180 mW/cm². The pressure of the chamber may be maintained between about 1 Tor and about 100 Torr, preferably between about 3 Torr and about 20 Torr, more preferably between about 4 Torr and about 12 Torr. The deposition rate of the p-type microcrystalline silicon contact layer may be about 10 Å/min or more. The p-type microcrystalline silicon contact layer has a crystalline fraction between about 20% and about 80%, preferably between about 50% and about 70%.

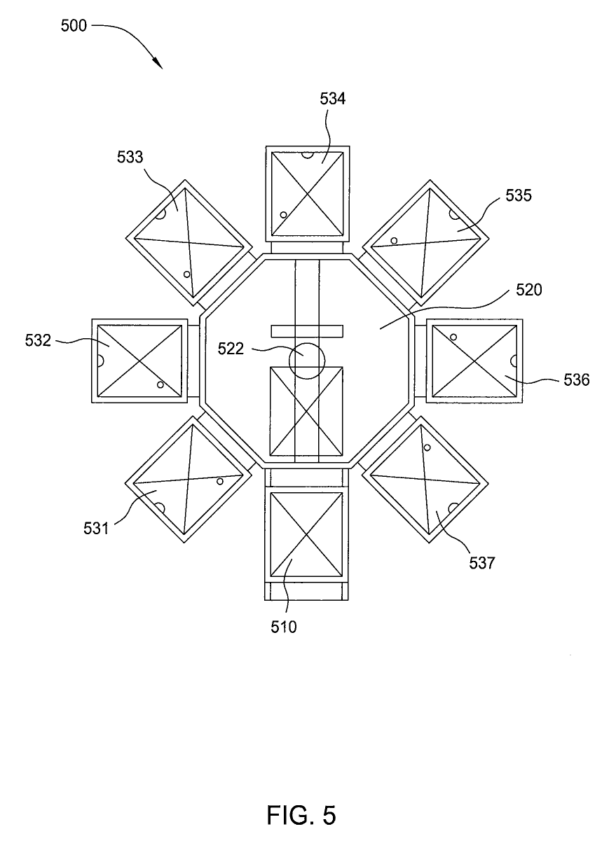

FIG. 5 is a top schematic view of one embodiment of a process system 500 having a plurality of process chambers 531-537, such as PECVD chamber 400 of FIG. 4 or other suitable chambers capable of depositing silicon films. The process system 500 includes a transfer chamber 520 coupled to a load lock chamber 510 and the process chambers 531-537. The load lock chamber 510 allows substrates to be transferred between the ambient environment outside the system and vacuum environment within the transfer chamber 520 and process chambers 531-537. The load lock chamber 510 includes one or more evacuatable regions holding one or more substrates. The evacuatable regions are pumped down during input of substrates into the system 500 and are vented during output of the substrates from the system 500. The transfer chamber 520 has at least one vacuum robot 522 disposed therein that is adapted to transfer substrates between the load lock chamber 510 and the process chambers 531-537. Seven process chambers are shown in FIG. 5; however, the system may have any suitable number of process chambers.

In certain embodiments of the invention, one system 500 is configured to deposit the first NIP junction comprising an intrinsic type microcrystalline silicon layer of a multi-junction, PV cell, such as the first NIP junction 120 of FIGS. 1-3. One of the process chambers 531-537 is configured to deposit the n-type silicon layer of the first NIP junction while the remaining process chambers 531-537 are each configured to deposit both the intrinsic type microcrystalline silicon layer and the p-type silicon layer. The intrinsic type microcrystalline silicon layer and the p-type silicon layer of the first NIP junction may be deposited in the same chamber without any passivation process in between the deposition steps. In certain embodiments, the time to process a substrate with the process chamber to form the n-type silicon layer is approximately four or more times faster, preferably six or more times faster, than the time to form the intrinsic type microcrystalline silicon layer and the p-type silicon layer in a single chamber. Therefore, in certain embodiments of the system, to deposit the first NIP junction, the ratio of n-chambers to i/p-chambers is 1:4 or more, preferably 1:6 or more. The throughput of the system including the time to provide plasma cleaning of the process chambers may be about three substrates/hr or more, preferably five substrates/hr or more.

In other embodiments of the invention, each of the process chambers 531-537 is configured to deposit the n-type silicon layer, the intrinsic type microcrystalline silicon layer, and the p-type silicon layer of the first NIP junction. In still other embodiments, a first dedicated process chamber is configured to deposit the n-type silicon layer, a second dedicated chamber is configured to deposit the intrinsic type microcrystalline silicon layer, and a third dedicated process chamber is configured to deposit the p-type silicon layer.

In other embodiments of the invention, one of the process chambers 531-537 is configured to deposit the p-type silicon layer of the first NIP junction while the remaining process chambers 531-537 are each configured to deposit both the n-type silicon layer and the intrinsic type microcrystalline silicon layer. The n-type silicon layer and the intrinsic type microcrystalline silicon layer of the first NIP junction may be deposited in the same chamber without any passivation process in between the deposition steps prior to depositing the p-type silicon layer in its dedicated chamber.

In certain embodiments of the invention, one system 500 is configured to deposit the second NIP junction comprising an intrinsic type amorphous silicon layer of a multi-junction, PV cell, such as the second NIP junction 130 of FIGS. 1-3. One of the process chambers 531-537 is configured to deposit the n-type silicon layer of the second NIP junction, while the remaining process chambers 531-537 are each configured to deposit both the intrinsic type amorphous silicon layer and the p-type silicon layer. The intrinsic type amorphous silicon layer and the p-type silicon layer of the second NIP junction may be deposited in the same chamber without any passivation process in between the deposition steps. Thus, a substrate enters the system through the load lock chamber 510, is transferred by the vacuum robot into the dedicated process chamber configured to deposit the n-type layer, is transferred by the vacuum robot into a process chamber to deposit both the intrinsic type silicon layer and the p-type silicon layer, and is transferred by the vacuum robot back to the load lock chamber 510. In certain embodiments, the time to process a substrate with the process chamber to form the n-type silicon layer is approximately four or more times faster, preferably six or more times faster, than the time to form the intrinsic type amorphous silicon layer and the p-type silicon layer in a single chamber. Therefore, in certain embodiments, the ratio of n-chambers to i/p-chambers is 1:4 or more, preferably 1:6 or more. The throughput of the system including the time to provide plasma cleaning of the process chambers may be about 10 substrates/hr or more, preferably 20 substrates/hr or more.

In other embodiments of the invention, each of the process chambers 531-537 is configured to deposit the n-type silicon layer, the intrinsic type amorphous silicon layer, and the p-type silicon layer of the second NIP junction. In still other embodiments, a first dedicated process chamber is configured to deposit the n-type silicon layer, a second dedicated chamber is configured to deposit the intrinsic type amorphous silicon layer, and a third dedicated process chamber is configured to deposit the p-type silicon layer.

In other embodiments of the invention, one of the process chambers 531-537 is configured to deposit the p-type silicon layer of the first NIP junction while the remaining process chambers 531-537 are each configured to deposit both the intrinsic type amorphous silicon layer and the n-type silicon layer. The n-type silicon layer and the intrinsic type amorphous silicon layer of the first NIP junction may be deposited in the same chamber without any passivation process in between the deposition steps.

In certain embodiments, the throughput of the system 500 for depositing the second NIP junction comprising an intrinsic type amorphous silicon layer is approximately two times or more the throughput of the system 500 for depositing the first NIP junction comprising an intrinsic type microcrystalline silicon layer since the thickness of the intrinsic type microcrystalline silicon layer is thicker than the intrinsic type amorphous silicon layer. Therefore, a single system 500 adapted to deposit a second NIP junction comprising intrinsic type amorphous silicon layers can be matched with two or more systems 500 adapted to deposit a first NIP junction comprising intrinsic type microcrystalline silicon layers. Once a first NIP junction has been formed on one substrate in one system, the substrate may be exposed to the ambient environment (i.e., vacuum break) and transferred to the second system. A wet or dry cleaning of the substrate between the first system depositing the first NIP junction and the second NIP junction is not necessary.

While the foregoing is directed to embodiments of the present invention, other and further embodiments of the invention may be devised without departing from the basic scope thereof, and the scope thereof is determined by the claims that follow.

1. A method of forming a thin film multi-junction photovoltaic structure, comprising:
selecting a translucent or transparent substrate;
forming a first transparent conductive oxide layer over the substrate;
forming a first NIP junction over the first transparent conductive oxide layer, comprising:
forming an n-type silicon layer;
forming an intrinsic type microcrystalline silicon layer over the n-type silicon layer; and
forming a p-type silicon layer over the intrinsic type microcrystalline silicon layer;
forming a second NIP junction over the first NIP junction, comprising:
forming an n-type silicon layer;
forming an intrinsic type amorphous silicon layer over the n-type silicon layer; and
forming a p-type silicon layer over the intrinsic type amorphous silicon layer;
forming a second transparent conductive oxide layer over the second NIP junction;
applying a top encapsulation layer over the second transparent conductive oxide layer; and
forming a reflective layer under the substrate.

2. The method of claim 1, wherein forming the second NIP junction further comprises forming an n-type amorphous silicon buffer layer between the n-type silicon layer and the intrinsic type amorphous silicon layer.

3. The method of claim 1, wherein forming the second NIP junction further comprises forming a p-type microcrystalline contact layer over the p-type silicon layer.

4. The method of claim 1 further comprising separating the photovoltaic structure into individual photovoltaic cells and interconnecting the photovoltaic cells via laser scribing through the substrate, prior to forming the reflective layer.

5. The method of claim 1, wherein the first NIP junction is formed in a first process system comprising a first process chamber and a second process chamber, wherein the n-type layer of the first NIP junction is formed in the first process chamber of the first process system and the intrinsic type layer and the p-type layer of the first NIP junction are formed in the second process chamber of the first process system, and wherein the second NIP junction is formed in a second process system comprising a first process chamber and a second process chamber, wherein the n-type layer of the second NIP junction is formed in the first process chamber of the second process system and the intrinsic type layer and the p-type layer of the second NIP junction are formed in the second process chamber of the second process system.

6. The method of claim 1, wherein the first NIP junction is formed in a first process system comprising a first process chamber and a second process chamber, wherein the n-type layer and the intrinsic type layer of the first NIP junction are formed in the first process chamber of the first process system and the p-type layer of the first NIP junction is formed in the second process chamber of the first process system, and wherein the second NIP junction is formed in a second process system comprising a first process chamber and a second process chamber, wherein the n-type layer and the intrinsic type layer of the second NIP junction are formed in the first process chamber of the second process system and the p-type layer of the second NIP junction is formed in the second process chamber of the second process system.

7. The method of claim 1, wherein the first NIP junction is formed in a first process system comprising a process chamber, wherein the n-type layer, the intrinsic type layer, and the p-type layer of the first NIP junction are formed in the process chamber of the first process system, and wherein the second NIP junction is formed in a second process system comprising a process chamber, wherein the n-type layer, the intrinsic type layer, and the p-type layer of the second NIP junction are formed in the process chamber of the second process system.

8. The method of claim 1, wherein the first NIP junction is formed in a first process system comprising a first process chamber, a second process chamber, and a third process chamber, wherein the n-type layer of the first NIP junction is formed in the first process chamber of the first process system, the intrinsic type layer of the first NIP junction is formed in the second process chamber of the first process system, and the p-type layer of the first NIP junction is formed in the third process chamber of the first process system, and wherein the second NIP junction is formed in a second process system comprising a first process chamber, a second process chamber, and a third process chamber, wherein the n-type layer of the second NIP junction is formed in the first process chamber of the second process system, the intrinsic type layer of the second NIP junction is formed in the second process chamber of the second process system, and the p-type layer of the second NIP junction is formed in the third process chamber of the second process system.

9. A thin film multi-junction photovoltaic structure, comprising:
a translucent or transparent substrate;
a first transparent conductive oxide layer formed over the substrate;
a first NIP junction formed over the first transparent conductive oxide layer, comprising:
an n-type silicon layer;
an intrinsic type microcrystalline silicon layer formed over the n-type silicon layer; and
a p-type silicon layer formed over the intrinsic type microcrystalline silicon layer;
a second NIP junction formed over the first NIP junction, comprising:
an n-type silicon layer;
an intrinsic type amorphous silicon layer formed over the n-type silicon layer; and
a p-type silicon layer formed over the intrinsic type amorphous silicon layer;
a second transparent conductive oxide layer formed over the second NIP junction;
a top encapsulation layer applied over the second transparent conductive oxide layer; and
a reflective layer formed under the substrate.

10. The photovoltaic structure of claim 9, wherein the second NIP junction further comprises an n-type amorphous silicon buffer layer between the n-type silicon layer and the intrinsic type amorphous silicon layer.

11. The photovoltaic structure of claim 9, wherein the second NIP junction further comprises a p-type microcrystalline contact layer formed over the p-type silicon layer.

12. A method of forming a thin film multi-junction photovoltaic structure, comprising:
selecting a translucent or transparent substrate;
forming a first transparent conductive oxide layer over the substrate;
performing a first laser scribing process through the substrate, wherein a strip of the first transparent conductive oxide layer is ablated;
forming a first NIP junction over the first transparent conductive oxide layer, comprising:
forming an n-type silicon layer;
forming an intrinsic type microcrystalline silicon layer over the n-type silicon layer; and
forming a p-type silicon layer over the intrinsic type microcrystalline silicon layer;
forming a second NIP junction over the first NIP junction, comprising:
forming an n-type silicon layer;
forming an intrinsic type amorphous silicon layer over the n-type silicon layer; and
forming a p-type silicon layer over the intrinsic type amorphous silicon layer;
performing a second laser scribing process through the substrate, wherein a first strip of the first and second NIP junctions are ablated;
forming a second transparent conductive oxide layer over the second NIP junction;
performing a third laser scribing process through the substrate, wherein a second strip of the first and second NIP junctions are ablated and a strip of the second transparent conductive oxide layer covering the second strip of the first and second NIP junctions is removed;
applying a top encapsulation layer over the second transparent conductive oxide layer; and
forming a reflective layer under the substrate.

13. The method of claim 12, wherein forming the second NIP junction further comprises forming an n-type amorphous silicon buffer layer between the n-type silicon layer and the intrinsic type amorphous silicon layer.

14. The method of claim 12, wherein forming the second NIP junction further comprises forming a contact layer over the p-type silicon layer.

15. An apparatus for forming a thin film multi-junction photovoltaic structure, comprising:
a first system configured to form a first NIP junction, comprising:
an n-chamber configured to deposit an n-type silicon layer; and
a p-chamber configured to deposit a p-type silicon layer; and
a second system configured to form a second NIP junction over the first NIP junction, comprising:
an n-chamber configured to deposit an n-type silicon layer; and
a p-chamber configured to deposit a p-type silicon layer.

16. The apparatus of claim 15, wherein the p-chamber of the first system is further configured to deposit an intrinsic type microcrystalline silicon layer, and wherein the p-chamber of the second system is further configured to deposit an intrinsic type amorphous silicon layer.

17. The apparatus of claim 16, wherein the ratio of n-chamber to p-chambers in the first system is 1:4 or greater and wherein the ratio of n-chamber to p-chambers in the second system is 1:4 or greater.

18. The apparatus of claim 16, wherein the ratio of the second system to the first system is 1:2 or greater.

19. The apparatus of claim 15, wherein the n-chamber of the first system is further configured to deposit an intrinsic type microcrystalline silicon layer, and wherein the n-chamber of the second system is further configured to deposit an intrinsic type amorphous silicon layer.

20. The apparatus of claim 19, wherein the ratio of p-chamber to n-chambers in the first system is 1:4 or greater and wherein the ratio of p-chamber to n-chambers in the second system is 1:4 or greater.

21. The apparatus of claim 19, wherein the ratio of the second system to the first system is 1:2 or greater.

22. The apparatus of claim 15, wherein the first system further comprises an i-chamber configured to deposit an intrinsic type microcrystalline silicon layer, and wherein the second system further comprises an i-chamber configured to deposit an intrinsic type amorphous silicon layer.

23. The apparatus of claim 22, wherein the ratio of the second system to the first system is 1:2 or greater.

24. An apparatus for forming a thin film multi-junction photovoltaic structure, comprising:
a first system configured to form a first NIP junction, comprising a chamber configured to deposit an n-type silicon layer, an intrinsic type microcrystalline silicon layer, and a p-type silicon layer; and
a second system configured to form a second NIP junction over the first NIP junction, comprising a chamber configured to deposit an n-type silicon layer, an intrinsic type amorphous silicon layer, and a p-type silicon layer.

25. The apparatus of claim 24, wherein the ratio of the second system to the first system is 1:2 or greater.
